(19) United States
(12) Patent Application Publication
(10) Pub. No.: US 2008/0245401 A1
(43) Pub. Date: Oct. 9, 2008

(54) CONCENTRATING PHOTOVOLTAIC SYSTEM USING A FRESNEL LENS AND NONIMAGING SECONDARY OPTICS

(75) Inventors: Roland Winston, Merced, CA (US); Alexander Ritschel, Merced, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: The Regents of the University of California, Oakland, CA (US)

(21) Appl. No.: 12/036,825

(22) Filed: Feb. 25, 2008

Related U.S. Application Data
(60) Provisional application No. 60/891,447, filed on Feb. 23, 2007.

(51) Int. Cl. H01L 31/052; G02B 3/08; G02B 5/08

(52) U.S. Cl. 136/246; 359/742; 359/851

(57) ABSTRACT

Optical devices and systems that provide high solar flux onto a multi-junction solar cell, or other target cell, to produce efficient electrical output. An optical device includes a primary focusing element, and a non-imaging secondary concentrator having an entry aperture and an exit aperture. The primary focus element is configured to focus light from a distant source onto the entry aperture of the secondary concentrator. The primary focusing element has an f-number that is greater than about 1, e.g., between 1 and 4 or greater. The device includes a solar cell located proximal to the exit aperture of the secondary concentrator. In certain aspects, the primary focusing element includes a Fresnel lens, a diffractive lens and/or a reflector. In certain aspects, a Fresnel lens used as the primary is flat, substantially square, curved and/or refractive.

### CROSS-REFERENCES TO RELATED APPLICATIONS

The present application claims priority to and is a nonprovisional application of U.S. Provisional Patent Ser. No. 60/891,447 filed Feb. 23, 2007. The disclosure of which is hereby incorporated by reference in its entirety for all purposes.

### STATEMENT AS TO RIGHTS TO INVENTIONS MADE UNDER FEDERALLY SPONSORED RESEARCH AND DEVELOPMENT

NOT APPLICABLE

### BACKGROUND

The present invention relates generally to optical devices, and more particularly to optical systems incorporating non-imaging optical components.

Solar cells for electrical energy production are very well known but have limited utility due to the very high cost of production. For example, although substantial research has been ongoing for many years, the cost per Killowatt-hour (Kwh) still is about ten times that of conventional electric power production. To compete with wind power or other alternative energy sources, the efficiency of production of electricity from solar cells should be drastically improved.

Therefore it is desirable to provide optical systems and methods that overcome the above and other problems. In particular, it is desirable to provide systems and methods that enhance the efficiency of collection of solar energy.

### BRIEF SUMMARY

The present invention provides systems and methods to concentrate light from a distant source, such as the sun, onto a target device, such as a solar cell.

Aspects of the present invention are directed to optical devices and systems that provide high solar flux onto a multi-junction solar cell, or other target cell, to produce efficient electrical output.

According to one aspect, an optical device is provided that typically includes a primary focusing element, and a non-imaging secondary concentrator having an entry aperture and an exit aperture. Typically, the primary focus element is configured to focus light from a distant source onto the entry aperture of the secondary concentrator. In certain aspects, the primary focusing element has an f-number that is greater than about 1, e.g., between 1 and 4 or greater. In certain aspects, the device includes a solar cell located proximal to the exit aperture of the secondary concentrator. In certain aspects, the primary focusing element includes a Fresnel lens. In certain aspects, the Fresnel lens is flat, substantially square, curved and/or refractive.

Reference to the remaining portions of the specification, including the drawings and claims, will realize other features and advantages of the present invention. Further features and advantages of the present invention, as well as the structure and operation of various embodiments of the present invention, are described in detail below with respect to the accompanying drawings. In the drawings, like reference numbers indicate identical or functionally similar elements.

### BRIEF DESCRIPTION OF THE DRAWINGS

FIG. 1 illustrates an optical device according to one embodiment.

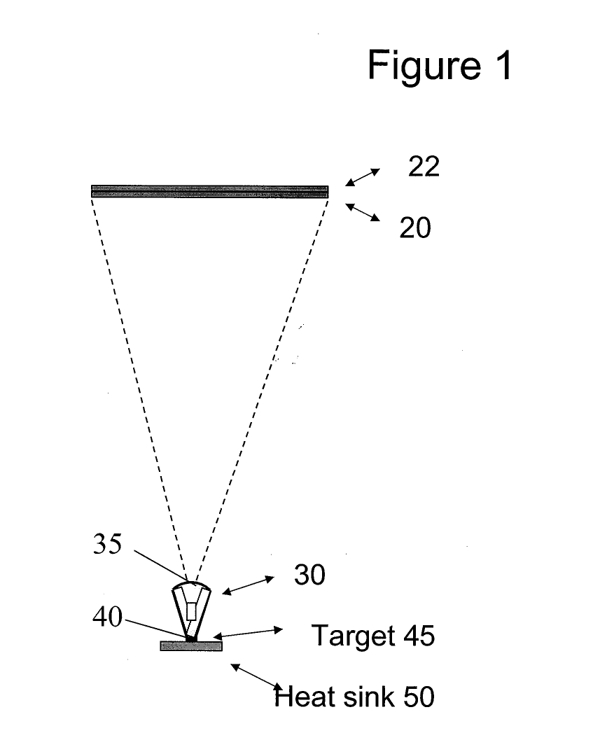

### DETAILED DESCRIPTION

The present invention provides systems and methods to concentrate light from a distant source, such as the sun, onto a target device, such as a solar cell.

According to one embodiment, an optical device 10 includes a primary focusing element 20, and a non-imaging secondary concentrator 30 having an entry aperture 35 and an exit aperture 40. In one aspect, the primary focus element 20 is configured to focus light from a distant source onto the entry aperture 35 of the secondary concentrator 30. Light received at the entry aperture 35 is provided to an exit aperture 40. In one aspect a target device 45 such as a solar cell is located proximal to the exit aperture 40 to receive the concentrated light. The target device 45 may be located above or below a plane defining the exit aperture, or it may be located substantially on the plane, or it may be optically coupled with the exit aperture.

In certain aspects, the primary focusing element 20 includes a lens element that has an f-number that is greater than about 1, e.g., between 1 and 4 or even greater. One example of a useful primary focusing element 20 is a substantially flat and square Fresnel lens. Other useful primary focusing elements include curved Fresnel lenses, non-square, flat Fresnel lenses, a Fresnel reflector, any focusing lens, a diffractive lens, a reflective element such as a mirror, a holographic lens element, or any other optical element that focuses or redirects light. In one aspect, a flat cover 22, e.g., made of glass or PMMA or other suitable optically transparent material, is positioned on or proximal to the primary focusing element on a side opposite the non-imaging secondary concentrator. Cover 22 provides additional environmental protection for the primary focusing element 20 or any other optical element, and allows the primary focusing element 20 to be very thin, e.g., a very thin layer.

In certain aspects, the device 10 also includes a means for homogenizing the light focused onto the entry aperture of the secondary concentrator. Examples of homogenizing elements or systems include Kohler homogenizers, holographic devices, kaleidoscopes, etc. U.S. patent application Ser. No. 11/683,934, filed Mar. 8, 2007, illustrates useful homogenizing elements and is incorporated herein by reference in its entirety. Also, U.S. patent application Ser. No. 11/084,882, filed Mar. 21, 2005, illustrates useful concentrator elements and other optical device features and is incorporated herein by reference in its entirety.

In certain aspects, the non-imaging secondary concentrator 30 is composed of a transparent dielectric material. In certain aspects, the non-imaging secondary concentrator 30 includes a compound parabolic concentrator (CPC), or a θₗ/θ_{O} angle transformer, or a flow line concentrator. For example, the secondary concentrator 30 may be made of a transparent dielectric material and may include a spherical or aspheric-shaped entrance aperture and a planar exit aperture. It should be appreciated that any concentrator element can be used. For example, the non-imaging secondary concentrator, in certain aspects, may operate by total internal reflection (TIR) and/or specular reflection. The region between the primary focusing element 20 and the concentrator 30 may be composed of air (n=1) or a solid transparent dielectric material having a different index of refraction than the concentrator, e.g., between 1 and 3, or greater. A liquid medium having a different index of refraction than the concentrator may also be used, in which case a body structure is included to hold the primary focusing element and concentrator and the liquid medium.

In certain aspects, the device advantageously has an optical acceptance angle of about ±5° or greater with an optical efficiency of between about 80-85%. In certain aspects, the devices of the present invention provide a uniform flux distribution on the target (e.g., solar cell) and are suitable for use with multi junction (MJ) and Si target cells, among others. In one specific embodiment, for example, a device might be configured with a 125 mm×125 mm entry aperture, a depth of about: 230 mm. Solar cell sizes for this embodiment might include a 5.5 mm×5.5 mm MJ cell or 10 mm×10 mm Si cell. This would provide a geometric concentration about 500 for the MJ cell or about 150 for the Si cell, with acceptance angles of about ±30 for the MJ cell or ±5° for the Si cell, and an optical efficiency of between about 80-85%.

It should be appreciated that target 45 may include a light source or an illumination element, in which case the optical system operates as an illuminator.

According to one embodiment, a heat sink 50 is provided on which to mount one or more optical systems. The heat sink may include a U-beam structure or comb structure as is well known, however other structures may be used as desired. The heat sink may also provide a platform on which to mount multiple systems. The target cell may be attached directly to the heat sink, or a heat spreader (e.g., Aluminum Nitride) may be provided to couple the heat sink with the target and enhance heat dissipation from the cell to the heat sink. In certain aspects, a tracking system is provided to reposition the system(s) as needed to track the motion of the sun and maintain the light impinging on the system within a desirable acceptance angle.

While the invention has been described by way of example and in terms of the specific embodiments, it is to be understood that the invention is not limited to the disclosed embodiments. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. An optical device, comprising:
a primary focusing element; and
a non-imaging secondary concentrator having an entry aperture and an exit aperture,
wherein the primary focus element is configured to focus light from a distant source onto the entry aperture of the secondary concentrator.

2. The device of claim 1, wherein the primary focusing element has an f-number that is greater than about 1.

3. The device of claim 1, wherein the primary focusing element includes a Fresnel lens.

4. The device of claim 3, wherein the Fresnel lens is flat.

5. The device of claim 4, wherein the Fresnel lens is substantially square.

6. The device of claim 3, wherein the Fresnel lens is curved.

7. The device of claim 3, wherein the Fresnel lens is refractive.

8. The device of claim 1, further comprising a means for homogenizing the light focused onto the entry aperture of the secondary concentrator.

9. The device of claim 1, further comprising a solar cell located proximal to the exit aperture of the secondary concentrator.

10. The device of claim 9, wherein the solar cell is optically coupled to the exit aperture of the secondary concentrator.

11. The device of claim 1, further comprising a glass cover that covers the primary focusing element on a side opposite the secondary concentrator.

12. The device of claim 1, wherein the non-imaging secondary concentrator is composed of a transparent dielectric material.

13. The device of claim 12, wherein the non-imaging secondary concentrator operates by total internal reflection.

14. The device of claim 12, wherein the non-imaging secondary concentrator operates by both total internal reflection and specular reflection.

15. The device of claim 1, wherein the primary focusing element includes a diffractive lens.

16. The device of claim 1, wherein the primary focusing element includes a reflector.

17. The device of claim 16, wherein the primary focusing element includes a Fresnel reflector.

18. The device of claim 1, wherein the secondary concentrator includes a compound parabolic concentrator (CPC).

19. The device of claim 1, wherein the secondary concentrator is composed of a transparent dielectric material and includes a spherical or aspheric-shaped entrance aperture.

20. The device of claim 1, wherein the secondary concentrator includes a θₗ/θ_{O} angle transformer.
